(19) United States
(12) Patent Application Publication
(10) Pub. No.: US 2003/0151077 A1
(43) Pub. Date: Aug. 14, 2003

(54) Method of forming a vertical double gate semiconductor device and structure thereof

(76) Inventors: Leo Mathew, Austin, TX (US); Bich-Yen Nguyen, Austin, TX (US); Michael Sadd, Austin, TX (US); Bruce E. White, Round Rock, TX (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 10/074,732

(22) Filed: Feb. 13, 2002

(51) Int. Cl. H01L 27/148

(52) U.S. Cl. 257/250; 257/328; 257/270; 257/331; 257/365

(57) ABSTRACT

A vertical double gate semiconductor device (10) having separate, non-contiguous gate electrode regions (62, 64) is described. The separate gate electrode regions can be formed by depositing a gate electrode material (28) and anisotropically etching, planarizing or etching back the gate electrode material to form the separate gate electrode regions on either side of the vertical double gate semiconductor device. One (66) or two (68, 70) contacts are formed over the separate gate electrode regions that may or may not be electrically isolated from each other. If formed from polysilicon, the separate gate electrode regions are doped. In one embodiment, the separate gate electrode regions are doped the same conductivity. In another embodiment, an asymmetrical semiconductor device is formed by doping one separate gate electrode region n-type and the other separate gate electrode region p-type.

### FIELD OF THE INVENTION

This invention relates generally to semiconductors, and more specifically, to the manufacture of and the structure of semiconductor devices.

### BACKGROUND OF THE INVENTION

As semiconductor devices continue to become smaller in size, the devices must be what is known in the industry as “scalable”. That is, the devices must continue to be able to be made with reduced dimensions and still function at the required specifications. One criteria that must be met is the threshold voltage of a metal oxide semiconductor field effect transistor (MOSFET). The threshold voltage is the voltage that is required to make the MOSFET become conductive. The threshold voltage must scale down as the power supply voltages used to power MOSFETs are reduced to smaller and smaller voltages.

Traditionally, MOSFETs have been implemented with a single control electrode or gate on a planar substrate. The gate is placed between a source and drain electrode and functioned to create a channel for controlling the amount of current conducted by the MOSFET. Because there is a single gate electrode to control the channel, there is only a single source of control of the channel. Single control of the channel leads to undesired leakage current (i.e. electron or hole flow) between the source and drain when the transistor is intended to be non-conductive.

An improved structure that was proposed was the use of a two-gate transistor with the gates on both sides of a thin silicon channel. This arrangement increases the electrostatic coupling between the gates and the channel relative to the single gate device. As a result, the drive current of the transistor is increased and the leakage current is decreased. One type of transistor having two gates is known in the art as FinFETs, in which the channel consists of a pillar or slab (a fin) that is oriented perpendicular to the plane of a substrate, but a line connecting the source and drain is parallel to the substrate plane. Additionally, the gate material of such a two-gate transistor is the same material type and in continuous contact. The most common gate material presently is polysilicon. A disadvantage with both gates constructed of polysilicon with the same type of doping is that the resulting threshold voltage of such gate structures is either around one volt or is below zero as in the case of a depletion mode device. This limited range of threshold voltage is unacceptable for modern applications where supply voltages are less than three volts. Others have used different doping concentrations within the same continuously connected gate material in an attempt to modify threshold voltages. Differing doping concentrations result in an issue with cross migration of dopants on both sides of a fin in a FinFET device. This cross migration of dopants leads to part of the gate structure functioning in a depletion mode or a very high threshold voltage mode. Differing doping concentrations also limit the amount of dopant diffusion drive that is necessary to reduce polysilicon depletion effects.

### BRIEF DESCRIPTION OF THE DRAWINGS

The present invention is illustrated by way of example and is not limited by the accompanying figures, in which like references indicate similar elements.

FIGS. 1-7 illustrate in cross-sectional form a process and structure for forming a semiconductor device having two electrode regions;

FIG. 8 illustrates in cross-sectional form a semiconductor device having isolated electrode regions in accordance with one embodiment of the present invention;

FIG. 9 illustrates in perspective form a semiconductor transistor having two control electrode regions in accordance with the present invention;

FIG. 10 illustrates in cross-sectional form a semiconductor device having electrically coupled electrode regions in accordance with another embodiment of the present invention;

FIG. 11 illustrates in cross-sectional form a semiconductor device having electrically isolated electrode regions in accordance with another embodiment of the present invention;

FIGS. 12 and 13 illustrate in cross-sectional form a semiconductor device having isolated electrode regions in accordance with another embodiment of the present invention;

FIG. 14 illustrates in cross-sectional form a semiconductor device having electrically coupled electrode regions in accordance with another embodiment of the present invention;

FIG. 15 illustrates in cross-sectional form a semiconductor device having electrically isolated electrode regions in accordance with yet another embodiment of the present invention; and

FIG. 16 illustrates in perspective form a semiconductor device in accordance with the present invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION

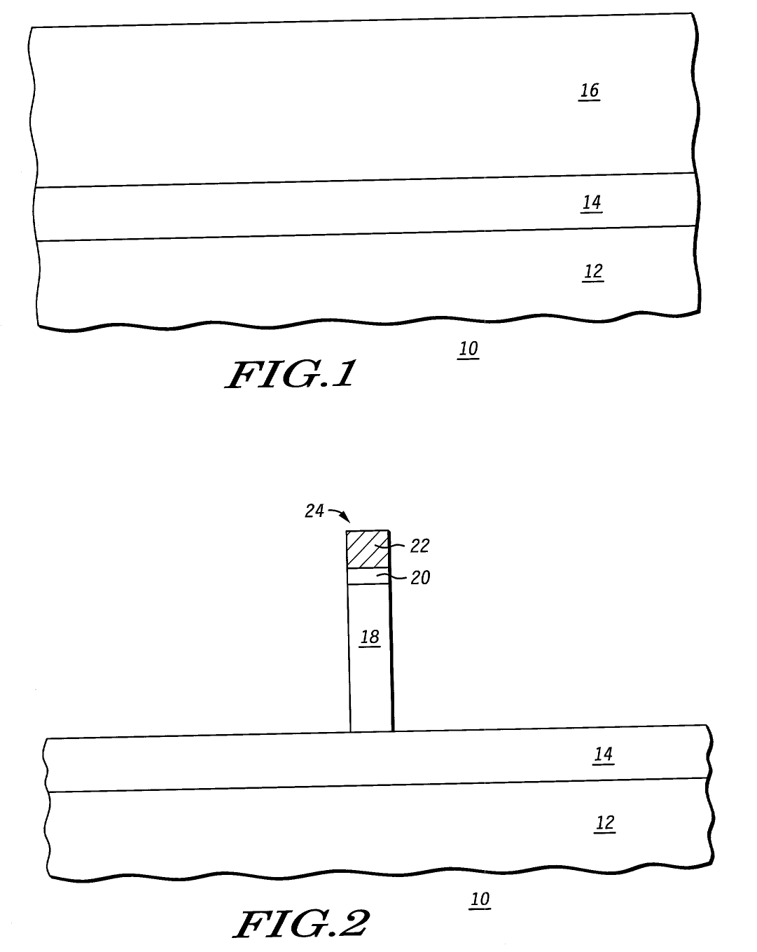

Illustrated in FIG. 1 is a cross-section of a semiconductor device 10 having a semiconductor substrate or substrate 12, an overlying first insulating layer or insulator 14 and an overlying semiconductor layer or layer 16. In one form, substrate 12 is silicon, but other materials may be used in lieu of silicon. Insulator 14 may be of any insulating material, such as an oxide or a nitride. Layer 16 in one form is polysilicon or silicon, but can also be of other materials. The three illustrated layers may be formed in any manner, such as by bonding, separation by implant, by deposition, by epitaxial growth or others.

Illustrated in FIG. 2 is a silicon layer 18 that is patterned from layer 16. Silicon layer 18 may be formed by several methods, including patterning and trimming or by depositing a hard mask and then etching. Silicon layer 18 has a first sidewall and a second sidewall opposite the first sidewall. Overlying silicon layer 18 is a pad oxide layer 20. Nitride layer 22 overlies the pad oxide layer 20. It should be well understood that the order of formation and location of nitride layer 22 and pad oxide layer 20 may be reversed or only one of the two layers may be used instead of using both. In combination, patterned silicon layer 18, pad oxide layer 20 and nitride layer 22 form a fin structure 24. Fin structure 24, in one form, may be formed by a blanket deposition of each layer and a subsequent selective etch, or fin structure 24 may be formed by a selective deposition of each layer.

Illustrated in FIG. 3 is a cross-section of further processing of semiconductor device 10. In particular, a second insulating layer in the form of a gate dielectric 26 is grown or deposited on all exposed surfaces of the silicon layer 18. The formation of gate dielectric 26 tends to form notches at the interface. A conductive layer in the form of a polysilicon layer 28 is blanket deposited onto semiconductor device 10. It should be appreciated that other conductive or semiconductive materials may be used instead of polysilicon layer 28, such as germanium or polysilicon germanium. The use of the term ‘conductive’ herein refers to both conductors and semiconductors as both classes of materials are or may be conductive.

Illustrated in FIG. 4 is a cross-section of further processing of semiconductor device 10. In particular, a directional implant 30 of a first conductivity type (N or P), i.e. a first species, is performed from a predetermined angle within an implant chamber. The direction of the implant is important as it should be noted that the directional implant 30 forms a first implant region 32 in a first area adjacent fin structure 24 and forms a second implant region 34. The important resulting feature of directional implant 30 is that no implant region is formed on the immediate right hand side of the fin structure 24. The first implant region 32 adjoins fin structure 24 on only one side and over the top region of fin structure 24 within polysilicon layer 28. This directional feature is important as an implant is performed in manner that does not uniformly surround the fin structure 24 with the same doping species. A directional implant may be implemented with conventional ion implanting equipment, as such equipment typically has the ability to tilt and rotate wafers to predetermined and required angles of incidence with the dopant species.

Illustrated in FIG. 5 is a cross-section of alternate processing of semiconductor device 10 that may be performed in lieu of the steps of FIG. 4. In FIG. 5, a photoresist mask 36 is provided to isolate semiconductor device 10 in all areas except at a predetermined distance from only one side of the fin structure 24. An alternate implant 30′ is then performed. In this embodiment, the implant 30′ may be either a straight implant or an angled implant. A resulting implant region 32′ results from the implant step of FIG. 5. It should be noted that other implants may be formed within polysilicon layer 28 for adjoining device structures. However, implant region 32′ is the only implant present close enough to fin structure 24 to have a significant influence on the gate structure being formed around fin structure 24.

Illustrated in FIG. 6 is a cross-section of further processing of semiconductor device 10 that is a continuation of the processing of FIG. 4. In FIG. 6, a directional implant 38 of a second conductivity type (P or N, depending upon the first implant), i.e. a second species, is performed from a second and different direction within the implant chamber. The direction of the implant is again important as it should be noted that the directional implant 38 forms a third implant region 40 in a second area adjacent the fin structure 24 that is different than the first area and forms a fourth implant region 42. The important resulting feature of directional implant 38 is that no implant region is formed on the immediate left hand side of the fin structure 24 as a result of this implant step. The third implant region 40 adjoins fin structure 24 on only one side and over the top region of fin structure 24 within polysilicon layer 28. This directional feature is important as an implant is performed in manner that does not uniformly surround the fin structure 24 with the same doping species. Therefore, at this point two physically separate or non-contiguous implants of differing conductivities are present around the fin structure 24. It should be understood that although separate conductivities are preferred, the same conductivity type with differing doses may be used in some applications depending upon the structure being formed. The depth of the implants illustrated herein are not necessarily drawn to scale and will vary depending upon the specifications of the device being fabricated.

Illustrated in FIG. 7 is a cross-section of further processing of semiconductor device 10 that is a continuation of the processing of FIG. 5. A photoresist mask 44 is placed overlying semiconductor device 10. Photoresist mask 44 is provided to isolate semiconductor device 10 in all areas except at a predetermined distance from a side of the fin structure 24 opposite where implant region 32′ is formed. An alternate implant 40′ is then performed. In this embodiment, the implant 40′ may be either a straight implant, as illustrated, or an angled implant. It should be noted that other implants may be formed within polysilicon layer 28 for adjoining device structures. However, implant regions 32′ and 40′ are the only implants that are present close enough to fin structure 24 to have a significant influence on the gate structure being formed around fin structure 24.

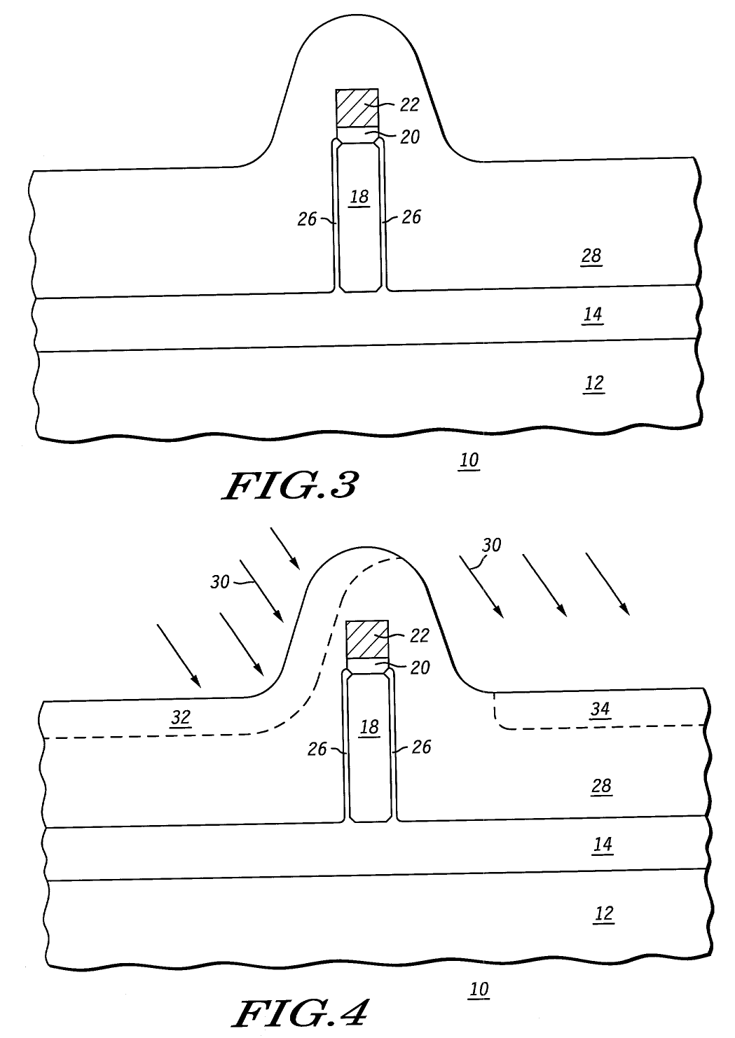

Illustrated in FIG. 8 is a cross-section of further processing of semiconductor device 10 that is a continuation of the processing of either FIG. 6 or 7. In FIG. 8, a chemical mechanical polish (CMP) step is performed wherein a portion of polysilicon layer 28 is removed or planarized in addition to a small portion of nitride layer 22. By using endpoint detection, the CMP step can be accurately stopped without removing more of nitride layer 22 than is desired. A substantially planar layer 50 results overlying the gate electrodes that have been formed. It should be noted that nitride layer 22 may also be removed by either of anisotropic etching or an etch back. The resulting semiconductor structure 10 now has physically separate and distinct gate structures in the form of first gate electrode 46 and second gate electrode 48. Again it should be noted that first gate electrode 46 is doped by a separate doping step than the second gate electrode 48. Therefore, migration of doping species between the two gate structures has been eliminated.

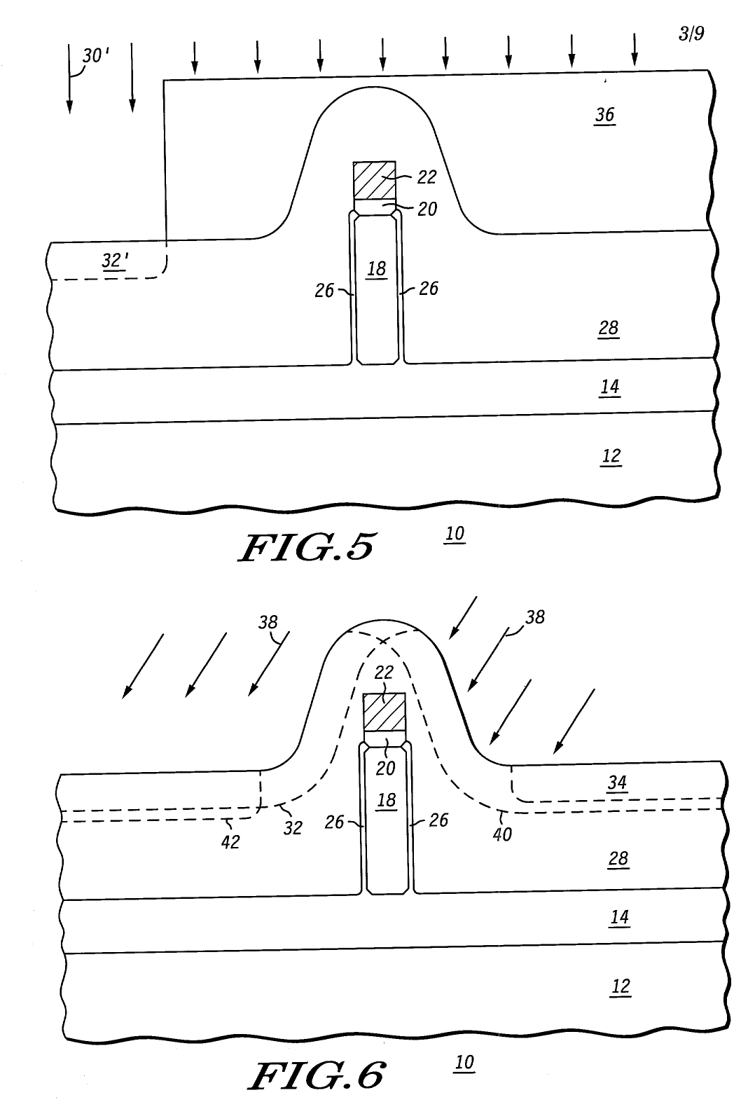

Illustrated in FIG. 9 is a perspective view of a composite transistor that uses the dual gate structure of FIG. 8. For convenience of comparison with common elements of FIG. 8, the same reference numbers will be used for like elements. A photoresist step is used to pattern the polysilicon layer 28 to expose current electrodes in the form of source/drain regions 52, 54 as illustrated in FIG. 9 wherein polysilicon layer 28 terminates into a pad region 50. It should be understood that a complementary pad region (not shown) may be formed on the opposite side of semiconductor device 10, if needed. The source/drain regions 52, 54 are extensions of the fin region 24 that will subsequently be doped to form the source and drain regions of a transistor. The channel region between the source and drain regions of the transistor are modulated by the two gate structures 46 and 48. The patterning of polysilicon layer 28 may be performed after a metal deposition (not shown).

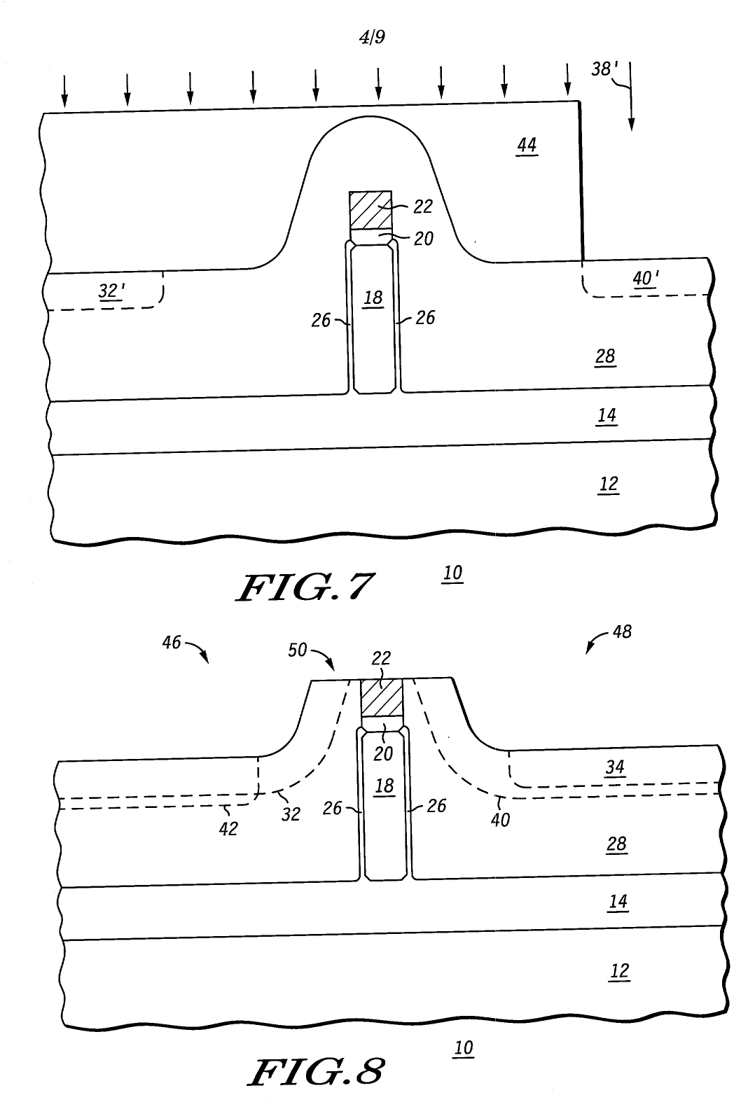

Illustrated in FIG. 10 is a cross-section of further processing of semiconductor device 10 that is a continuation of the processing of FIG. 8. In FIG. 10 a deposition of a metal layer 56 is illustrated to electrically connect the first gate 46 with the second gate 48. Any of numerous metal or conductive materials may be used for metal layer 56. For example, tungsten, polysilicon, amorphous silicon, titanium, tantalum, their nitrides or a combination of some of the above. Additionally, other metals, a metal nitride layer or a metal silicon nitride layer may be used. Preferably, metal layer 56 is formed by a deposition process. It should be noted that metal layer 56 as well as other metal layers subsequently referenced herein may be formed as a stack of metal layers. As an example, any of the illustrated metal layers may be formed as a metallic stack of a tantalum nitride layer and a titanium nitride layer.

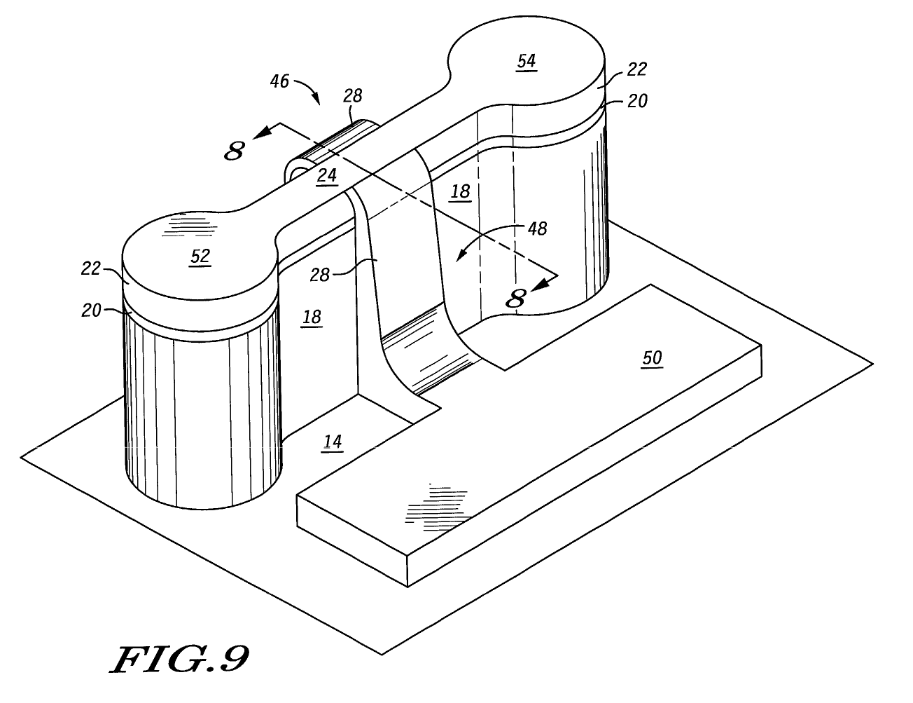

Illustrated in FIG. 11 is a cross-section of further processing of semiconductor device 10 that is a continuation of the processing of FIG. 10. A CMP step is performed to result in the semiconductor device 10 of FIG. 11 having a first contact 58 created from metal layer 56 and a second contact 60 created from metal layer 56. Metal layer 56 is planarized by the CMP step. Endpoint detection is used to determine an accurate stop of the polishing to thereby leave the desired structure of FIG. 11. At this point, electrical contact to first gate 46 is made separate and distinct from electrical contact to second gate 48. Typically, both the first gate 46 and second gate 48 are electrically connected. However, the structure of FIG. 11 permits for certain applications the ability to implement the present invention with separate and independent control of two gates in a single device. Separate control may provide for easier implementation of certain logic gates and Boolean functions. Separate control of the channel region helps with device characterization and provides flexibility in the control of the channel in analog applications that are susceptible to processing and manufacturing variations.

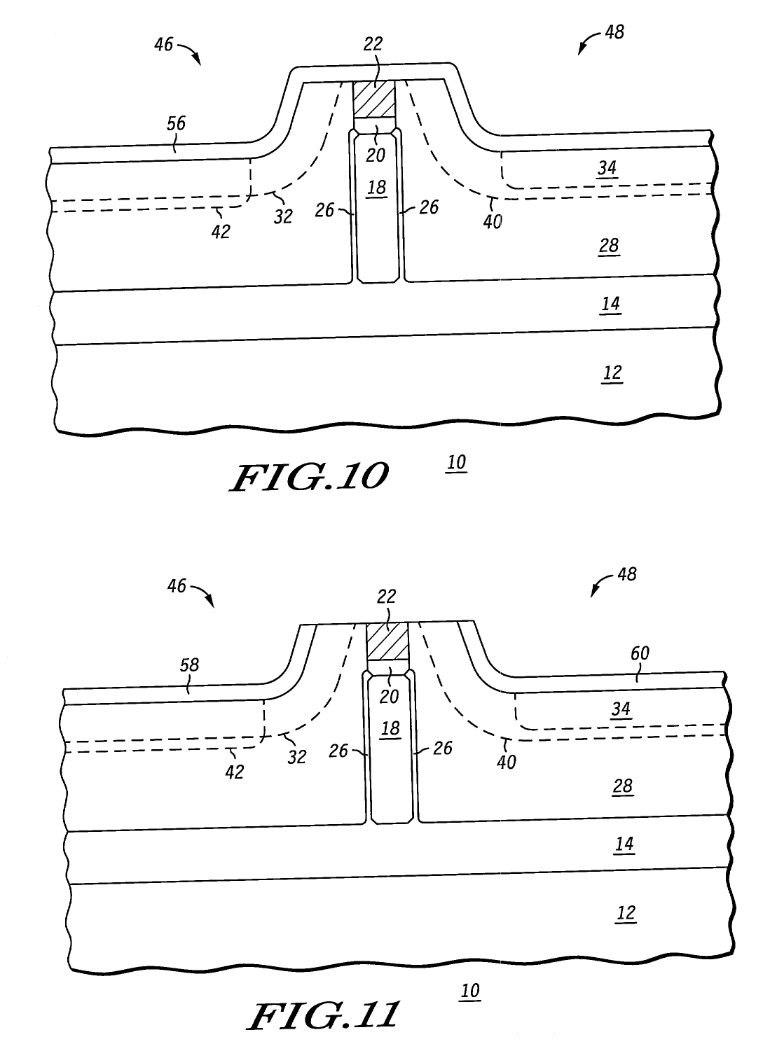

Illustrated in FIG. 12 is a cross-section of further processing of semiconductor device 10 that is a continuation of the processing of either FIG. 6 or 7. An optional intervening anneal step may be implemented for device 10 of either FIG. 6 or 7. Illustrated in FIG. 12 is a spacer etch performed as an anisotropic etch to create a first electrode region and a second electrode region in the respective form of polysilicon regions 62 and 64, each being adjacent a sidewall of fin structure 24. The spacer etch is performed in lieu of a CMP process. The spacer etch has the effect of creating physically separate gate electrode regions in the form of first implant region 32 and third implant region 40 to have physically separate doping regions. Rather than implanting at an earlier time to create first implant region 32 and third implant region 40, an alternative is to create the two implant regions at this point in the process in a directional manner as described before. Any implant that gets diffused into oxide layer 14 will not be detrimental as it will be electrically inactive in the oxide that functions as an insulator.

FIG. 13 is a cross-section of further processing of semiconductor device 10 that is a continuation of the processing of FIG. 12. In FIG. 13 an anneal of the semiconductor device 10 is performed to enhance the diffusion. In other words, the annealing of polysilicon regions 62 and 64 to form polysilicon regions 62′ and 64′ activates the diffusion species and creates a more uniform distribution. The more uniform distribution reduces polysilicon depletion effects along the perimeter of gate structures 46 and 48 adjoining the channel. The fact that the gate structures 46 and 48 are physically and electrically separated permits the ability to obtain uniform dopant redistribution without cross migration. The anneal step thereby forms polysilicon regions 62′ and 64′.

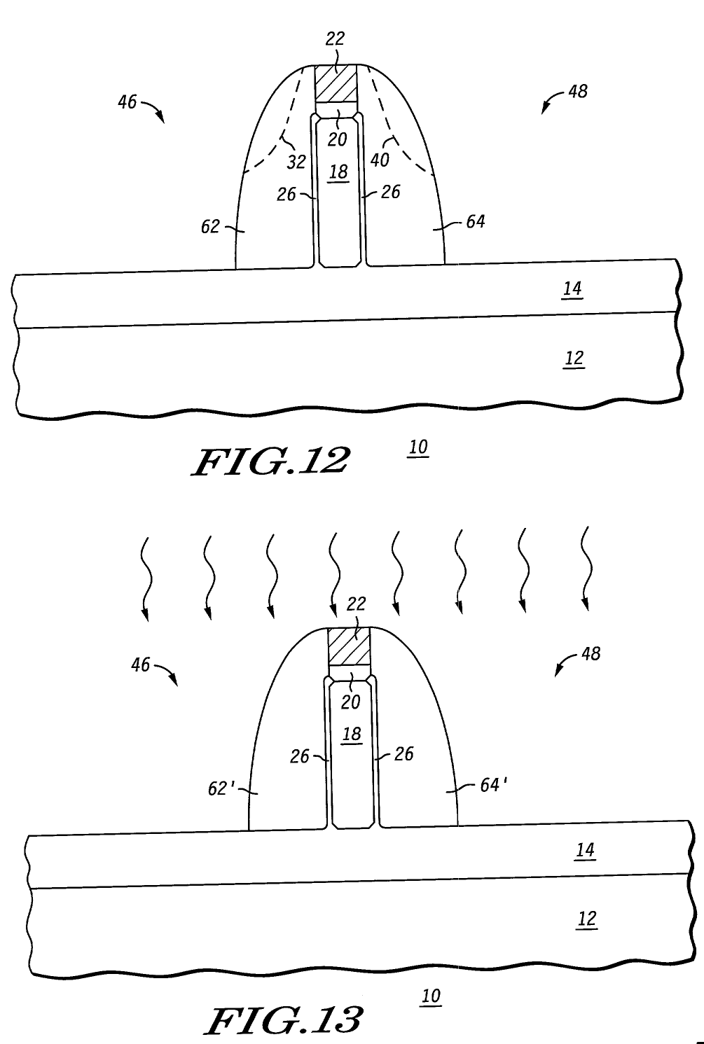

FIG. 14 is a cross-section of further processing of semiconductor device 10 that is a continuation of the processing of FIG. 13. In FIG. 13 a deposition of a metal layer 66 is illustrated to electrically connect the first gate 46 with the second gate 48. Again, any of numerous metal or conductive materials may be used for metal layer 66. For example, tungsten, polysilicon, amorphous silicon, titanium, tantalum, their nitrides or a combination of some of the above. Preferably, metal layer 66 is formed by a deposition process. Semiconductor device 10 may be heated to form a conductive silicide at all areas where silicon or polysilicon and metal interface.

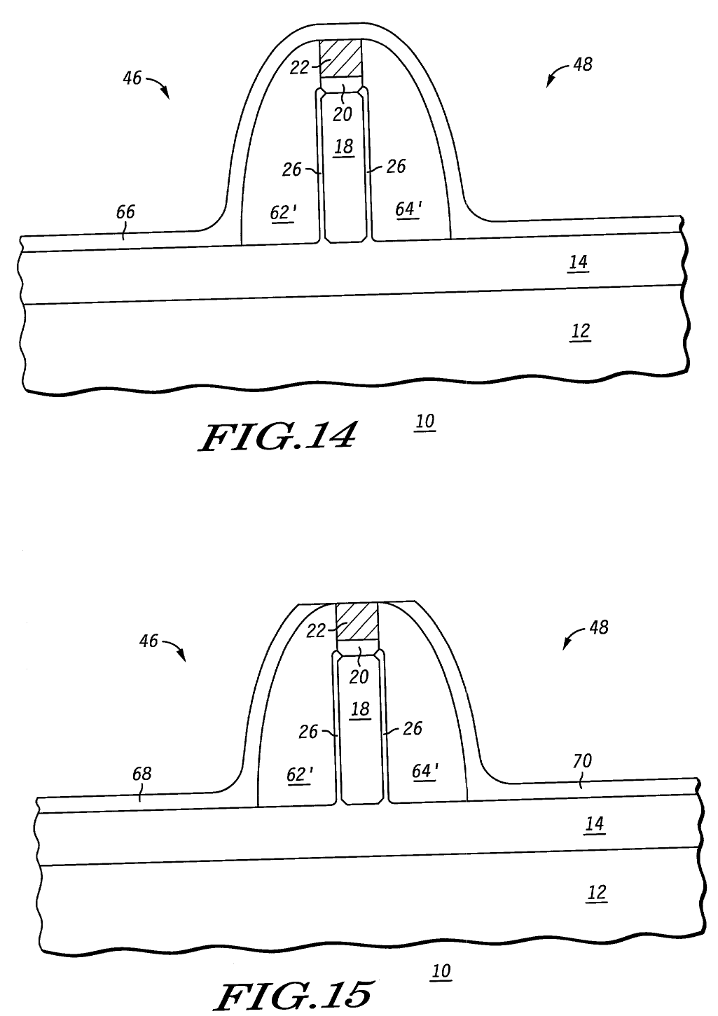

FIG. 15 is a cross-section of further optional processing of semiconductor device 10 that is a continuation of the processing of FIG. 14. Device 10 has been processed to electrically isolate first gate 46 from second gate 48. The metal layer 66 is either etched or chemically mechanically polished or unsilicided metal regions cleaned away around the nitride layer 22. The result is to obtain a first metal layer 68 making electrical contact to first gate 46 and to obtain a second metal layer 70 making electrical contact to second gate 48. A subsequent uniform deposition of a nitride layer (not shown) may be implemented to assist with subsequent drain and source diffusion processing.

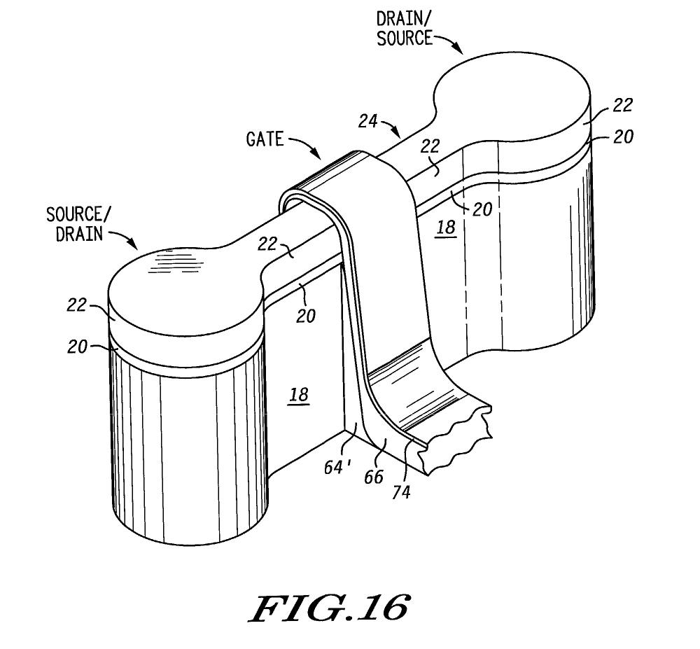

Illustrated in FIG. 16 is a semiconductor device perspective using the semiconductor device 10 of FIG. 14. For convenience of explanation purposes, the same reference numbers will be used for elements common between FIG. 14 and FIG. 16. At this point, conventional processing may be used to define the gate region of a transistor using a blanket nitride deposition followed by patterning the nitride to form a nitride layer 74. The patterning also includes patterning the metal layer 66 to form patterned metal layer 66. The patterning also includes patterning the polysilicon regions 62′ and 64′. Additionally, conventional processing may be used to form source and drain regions of the transistor adjacent the gate region using source and drain implants. The nitride 74 and the metal layer 66 prevent any ions from entering into polysilicon regions 62′ and 64′ during the source/drain implant. Electrical contacts (not shown) to the source and drain may be formed by forming nitride spacers on the structure and siliciding all exposed silicon regions. Electrical contact to the gate is made via the metal routing of metal layer 66.

By now it should be appreciated that there has been provided a vertical double gate semiconductor device having first and second control electrodes adjoining a channel region. The semiconductor device may function as a transistor (any type, e.g. MOSFET, FinFET, DGFET, or bipolar if the gate oxide is removed), a capacitor or a diode. The process taught herein is self-aligned because the two gate structures are aligned to each other as a result of the common, symmetrical formation. The device taught herein may be scaled to smaller geometries with proportional characteristic scaling. A common semiconductor material, such as polysilicon, may be used as the gate material while achieving low threshold voltages, such as near zero to 0.4 volts for example. Although many differing gate materials may be used in conjunction with this process and structure, no gate material engineering involving obscure work-function materials is required.

By using alternate P and N conductivities for the gate materials of the two gates, the threshold voltage of the device can be accurately controlled to function in the low threshold voltage ranges required. Further, by using separated P and N regions, the gates can be uniformly doped to obtain consistent and predictable threshold voltage performance.

For devices created herein where a CMP step such as in FIG. 8 is used, if the polysilicon height of polysilicon layer 28 is made to approximate the fin height of fin structure 24, the polysilicon sheet resistance is reduced and thereby allows faster switching characteristics.

Although the method and structure taught herein has been disclosed with respect to certain specific steps and materials, it should be readily apparent that various alternatives may be used. Source and drain electrodes may be used with polysilicon material. Gate dielectrics other than silicon dioxide may be used. The height of the fin structure, including specific component elements, may be varied significantly. The width of the gate sidewall structure and contacting metal may be made wide enough to be in close proximity to each adjoining source/drain region depending upon the specific channel length desired for an application.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A method of forming a vertical double gate semiconductor device comprising:
providing a semiconductor substrate;
providing a first insulating layer over the semiconductor substrate;
providing a first semiconductor layer over the first insulating layer;
removing portions of the first semiconductor layer to form a semiconductor structure having a first sidewall and a second sidewall, wherein the first sidewall is opposite the second sidewall;
forming a first current electrode region and a second current electrode region in the semiconductor substrate;
forming a second insulating layer adjacent the first sidewall and the second sidewall;
forming a conductive layer over the semiconductor structure and the second insulating layer; and
removing a portion of the conductive layer to form a first electrode region and a second electrode region, wherein:
the first electrode region is adjacent the first sidewall of the semiconductor structure;
the second electrode region is adjacent the second sidewall of the semiconductor structure; and
the first electrode region and the second electrode region are physically isolated from each other.

2. The method of claim 1 wherein the semiconductor structure is a channel region of the vertical double gate semiconductor device.

3. The method of claim 1 wherein removing the portions of the conductive layer comprises anisotropically etching the conductive layer.

4. The method of claim 1 wherein removing the portions of the conductive layer comprises planarizing the conductive layer.

5. The method of claim 1 wherein forming the conductive layer further comprises:
forming a second semiconductor layer; and
doping the second semiconductor layer in a first area adjacent the semiconductor structure with a first species.

6. The method of claim 5, further comprising doping the second semiconductor layer in a second area adjacent the semiconductor structure with a second species, wherein the second species is different than the first species and the second area is different than the first area.

7. The method of claim 6, wherein doping the second semiconductor layer is performed by ion implantation at an angle relative to a top surface of the semiconductor substrate.

8. The method of claim 6, further comprising annealing the first electrode region and the second electrode region after doping the second semiconductor layer.

9. The method of claim 6, wherein removing a portion of the conductive layer is performed after doping the second semiconductor layer in a first area adjacent the semiconductor structure with a first species.

10. The method of claim 6, wherein the first area is part of the first electrode region and the second area is part of the second electrode region.

11. The method of claim 1, further comprising forming metal over the first electrode region and the second electrode region.

12. The method of claim 1, wherein forming the metal comprises:
forming a silicon layer over the first electrode region, the second electrode region, and the semiconductor structure;
forming a first metal layer over the silicon layer; and
heating the semiconductor substrate so that the silicon layer and the first metal layer form a silicide.

13. The method of claim 12, further comprising: removing a portion of the metal to form a first contact for the first electrode region and a second contact for the second electrode region, wherein the first contact and the second contact are electrically isolated from each other.

14. The method of claim 13, wherein removing a portion of the metal comprises planarizing the metal.

15. The method of claim 11, further comprising annealing the first electrode region and the second electrode region before forming the metal.

16. The method of claim 11, wherein the metal is a stack of metal layers.

17. A method of forming a vertical double gate semiconductor device comprising:
providing a semiconductor substrate;
forming a first insulating layer over the semiconductor substrate;
forming a first semiconductor layer on the first insulating layer;
etching portions of the first semiconductor layer to form a semiconductor structure having a first sidewall and a second sidewall, wherein the first sidewall is opposite the second sidewall in a first direction;
forming a source region and a drain region in the semiconductor substrate in a second direction, wherein the first direction is substantially perpendicular the second direction;
forming a second insulating layer on the first sidewall and the second sidewall;
forming a second semiconductor layer over the semiconductor structure and the second insulating layer, wherein the second semiconductor layer comprises:
a first semiconductor portion which is adjacent the first sidewall;
a second semiconductor portion which is over the semiconductor structure; and
a third semiconductor portion which is adjacent the second sidewall;
doping the first semiconductor portion and the third semiconductor portion; and
removing the second semiconductor portion.

18. The method of claim 17, wherein the second insulating layer is deposited conformally.

19. The method of claim 17 further comprising annealing the second semiconductor layer.

20. The method of claim 19 wherein annealing is performed after removing the second semiconductor portion.

21. The method of claim 17 wherein removing the second portion is performed by a method selected from the group of anisotropic etching, planarization and etch back.

22. The method of claim 17 wherein doping the first semiconductor portion and the third semiconductor portion further comprises doping the first semiconductor portion with a first species and doping the third semiconductor portion with a second species, wherein the first species and the second species are different in conductivity.

23. The method of claim 17, wherein doping the first semiconductor portion and the third semiconductor portion is performed by ion implanting species at an angle relative to a top surface of the semiconductor substrate.

24. The method of claim 17, wherein doping the first semiconductor portion and the third semiconductor portion further includes forming a patterned layer over the semiconductor substrate.

25. The method of claim 17, wherein etching portions of the first semiconductor layer to form the semiconductor structure further comprises:
forming a third insulating layer over the first semiconductor layer;
forming a nitride layer over the third insulating layer;
patterning the nitride layer and the third insulating layer; and
etching the first semiconductor layer using the nitride layer and the third insulating layer as a mask.

26. A vertical double gate semiconductor device comprising:
a semiconductor substrate;
a first insulating layer over the semiconductor substrate;
a semiconductor structure over the first insulating layer having a first current electrode region, a second current electrode region, a first sidewall and a second sidewall, wherein:
the first current electrode region and the second current electrode region are separated by a channel region in a first direction; and
the first sidewall and the second sidewall are opposite each other in a second direction, wherein the first direction is substantially perpendicular to the second direction;
a first control electrode region over the first sidewall; and
a second control electrode region over the second sidewall, wherein the first control electrode region and second control electrode region are not contiguous portions of a same material.

27. The vertical double gate semiconductor device of claim 26 wherein the first control electrode region and the second control electrode region are doped.

28. The vertical double gate semiconductor device of claim 26 wherein the first control electrode region is doped with a different species than the second control electrode region.

29. The vertical double gate semiconductor device of claim 26 wherein the first control electrode region is doped n-type and the second control electrode region is doped p-type.

30. The vertical double gate semiconductor device of claim 26 wherein a first contact is formed over the first control electrode region and a second contact is formed over the second control electrode region, wherein the first contact and the second contact are electrically isolated from each other.

31. The vertical double gate semiconductor device of claim 26 wherein a metallic layer is formed over the first control electrode region, the second control electrode region and the channel region.

32. The vertical double gate semiconductor device of claim 31 wherein the metallic layer comprises a metal nitride layer or a metal silicon nitride layer.

33. The vertical double gate semiconductor device of claim 26 wherein the semiconductor substrate and the semiconductor structure comprise silicon.
